(19) United States
(12) Patent Application Publication
(10) Pub. No.: US 2017/0022609 A1
(43) Pub. Date: Jan. 26, 2017

(54) Heteroleptic Diazadiene-Containing Tungsten Precursors for Thin Film Deposition

(71) Applicant: Applied Materials, Inc., Santa Clara, CA (US)

(72) Inventors: Thomas Knisley, Monroe, MI (US); David Thompson, San Jose, CA (US)

(21) Appl. No.: 15/215,041

(22) Filed: Jul. 20, 2016

Related U.S. Application Data
(60) Provisional application No. 62/194,744, filed on Jul. 20, 2015.

(51) Int. Cl. C23C 16/455; C07F 11/00

(52) U.S. Cl. CPC C23C 16/45525; C07F 11/005

(57) ABSTRACT

Tungsten precursors represented by the formula W(ND)ₓ(DAD)_{y}R_{z}, where each ND is a neutral donor, each DAD is a diazadiene, each R is an anionic or dianionic ligand and x is in the range of 0 to 4, y is in the range of 1 to 3, z is in the range of 0 to 4 and x+z is greater than or equal to 1. Methods of depositing a film using the tungsten precursors are provided.

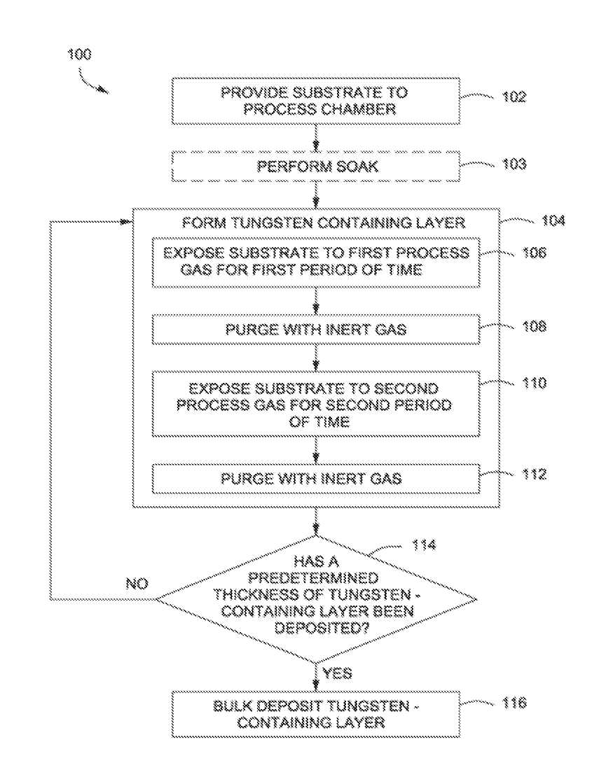

### CROSS-REFERENCE TO RELATED APPLICATIONS

This application claims priority to U.S. Provisional Application No. 62/194,744, filed Jul. 20, 2015, the entire disclosure of which is hereby incorporated by reference herein.

### FIELD

Embodiments of the disclosure relate to tungsten precursors for thin film deposition. More particularly, embodiments of the disclosure are directed to heteroleptic diazadiene-containing tungsten precursors and methods of use.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deliver precursor molecules on a substrate surface in sequential cycles. The cycle exposes the substrate surface to a first precursor, a purge gas, a second precursor and the purge gas. The first and second precursors react to form a product compound as a film on the substrate surface. The cycle is repeated to form the layer to a desired thickness.

The advancing complexity of advanced microelectronic devices is placing stringent demands on currently used deposition techniques. Unfortunately, there is a limited number of viable chemical precursors available that have the requisite properties of robust thermal stability, high reactivity, and vapor pressure suitable for film growth to occur. In addition, precursors that often meet these requirements still suffer from poor long-term stability and lead to thin films that contain elevated concentrations of contaminants such as oxygen, nitrogen, and/or halides that are often deleterious to the target film application. Therefore, there is a need in the art for improved thin film precursors for tungsten.

### SUMMARY

One or more embodiments of the disclosure are directed to metal coordination complexes having a formula represented by W(ND)ₓ(DAD)_{y}R_{z}. Each ND is a neutral donor, each DAD is a diazadiene, each R is an anionic or dianionic ligand and x is in the range of 0 to 4, y is in the range of 1 to 3, z is in the range of 0 to 4 and x+z is greater than or equal to 1.

Additional embodiments of the disclosure are directed to processing methods comprising sequentially exposing a substrate to a first reactive gas and a second reactive gas to form a tungsten-containing film. The first reactive gas comprises a tungsten-containing compound comprising a compound with the representative formula W(ND)ₓ(DAD)_{y}R_{z}, where each ND is a neutral donor, each DAD is a diazadiene, each R is an anionic or dianionic ligand and x is in the range of 0 to 4, y is in the range of 1 to 3, z is in the range of 0 to 4 and x+z is greater than or equal to 1.

Further embodiments of the disclosure are directed to processing methods comprising exposing a substrate to a first reactive gas comprising a tungsten-containing compound and a second reactive gas to form a tungsten-containing film. The tungsten-containing compound comprises a compound with the representative formula W(ND)ₓ(DAD)_{y}R_{z}, where each ND is a neutral donor, each DAD is a diazadiene, each R is an anionic or dianionic ligand and x is in the range of 0 to 4, y is in the range of 1 to 3, z is in the range of 0 to 4 and x+z is greater than or equal to 1.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

The FIGURE illustrates an exemplary process sequence for the formation of a tungsten layer using a two pulse cyclical deposition technique according to one embodiment described herein.

### DETAILED DESCRIPTION

Embodiments of the disclosure provide an improved process for depositing tungsten-containing films. The process of various embodiments uses vapor deposition techniques, such as an atomic layer deposition (ALD) to provide tungsten films having significantly improved surface uniformity and production level throughput.

Embodiments of the disclosure are directed to a series of heteroleptic diazadiene and/or diazadienyl-containing tungsten precursors for thin film deposition applications of the formula W(ND)ₓ(DAD)_{y}(R)_{z}; whereas ND is a neutral donor like CO (carbonyl), DAD is a diazadiene, and R is an anionic or dianionic metallorganic ligand (ex: cyclopentadienyl, etc). This new chemical class can be used to form highly-pure tungsten films with low impurities of carbon, nitrogen, and oxygen. Without being bound by any particular theory of operation, the low impurity level is believed to be due to the chemical nature of the W-DAD bond. Such a film is highly coveted in, for example, gate contact applications where low resistivity and high tungsten film purity is sought. This highly reactive system is believed to yield a reduced tungsten metal center and free diazadiene which is liberated into the purge gas stream preventing unwanted incorporation into the newly produced tungsten metal thin film.

A “substrate surface”, as used herein, refers to any portion of a substrate or portion of a material surface formed on a substrate upon which film processing is performed. For example, a substrate surface on which processing can be performed include materials such as silicon, silicon oxide, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride. A substrate surface may also include dielectric materials such as silicon dioxide and carbon doped silicon oxides. Substrates may have various dimensions, such as 200 mm or 300 mm diameter wafers, as well as, rectangular or square panes. In some embodiments, the substrates comprises a rigid discrete material.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness.

In an aspect of a spatial ALD process, a first reactive gas and second reactive gas (e.g., hydrogen radicals) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

The FIGURE depicts a method for forming a tungsten-containing layer on a substrate in accordance with some embodiments of the disclosure. The method 100 generally begins at 102, where a substrate, having a surface upon which a tungsten-containing layer is to be formed is provided and placed into a processing chamber. As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the tungsten-containing layer, for example, by polishing, etching, reduction, oxidation, halogenation, hydroxylation, annealing, baking, or the like.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate such that the tungsten-containing layer may be at least partially formed thereon. For example, in some embodiments, a layer comprising a metal, a nitride, an oxide, or the like, or combinations thereof may be disposed on the substrate and may have the tungsten containing layer formed upon such layer or layers.

In some embodiments, the substrate may be exposed to an optional soak process 103 prior to beginning the cyclical deposition process to form a tungsten-containing layer on the substrate (as discussed below at 104), as shown in phantom at 103. In one or more embodiments, the method of depositing the tungsten-containing layer on the substrate 104 does not include a soaking process.

At 104, a tungsten-containing layer is formed on the substrate. The tungsten-containing layer may be formed via a cyclical deposition process, such as atomic layer deposition (ALD), or the like. In some embodiments, the forming of a tungsten-containing layer via a cyclical deposition process may generally comprise exposing the substrate to two or more process gases sequentially. In time-domain ALD embodiments, exposure to each of the process gases are separated by a time delay/pause to allow the components of the process gases to adhere and/or react on the substrate surface. Alternatively, or in combination, in some embodiments, a purge may be performed before and/or after the exposure of the substrate to the process gases, wherein an inert gas is used to perform the purge. For example, a first process gas may be provided to the process chamber followed by a purge with an inert gas. Next, a second process gas may be provided to the process chamber followed by a purge with an inert gas. In some embodiments, the inert gas may be continuously provided to the process chamber and the first process gas may be dosed or pulsed into the process chamber followed by a dose or pulse of the second process gas into the process chamber. In such embodiments, a delay or pause may occur between the dose of the first process gas and the second process gas, allowing the continuous flow of inert gas to purge the process chamber between doses of the process gases.

In spatial ALD embodiments, exposure to each of the process gases occurs simultaneously to different parts of the substrate so that one part of the substrate is exposed to the first reactive gas while a different part of the substrate is exposed to the second reactive gas (if only two reactive gases are used). The substrate is moved relative to the gas delivery system so that each point on the substrate is sequentially exposed to both the first and second reactive gases. In any of the embodiments described above for both time-domain ALD and spatial ALD processes, the sequences may be repeated until a desired layer thickness is formed on the substrate surface.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

The process of forming the tungsten-containing layer at step 104 may begin by exposing the substrate to a first reactive gas. In some embodiments, the first reactive gas comprises a tungsten precursor (also referred to as a tungsten-containing gas, and the like) and is exposed to the substrate for a first period of time, as shown at 106.

In some embodiments, the tungsten-containing gas comprises a tungsten precursor, also referred to as a tungsten metal coordination complex. The tungsten precursor has a formula represented by W(ND)ₓ(DAD)_{y}R_{z}, where each ND is a neutral donor, each DAD is a diazadienyl or diazadiene, each R is an anionic or dianionic ligand and x is in the range of 0 to 4, y is in the range of 1 to 3 and z is in the range of 0 to 4.

In some embodiments, at least one DAD is represented by the formula

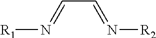

where each of R₁ and R₂ are independently selected from H, C1-6 alkyl, aryl, acyl, alkylamido, hydrazido, silyl, aldehyde, keto, C2-4 alkenyl and/or alkynyl groups.

In one or more embodiments, at least one DAD is represented by the formula

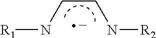

where the DAD consists of a delocalized radical anion and is negatively charged. Each of R₁ and R₂ are independently selected from H, C1-6 alkyl, aryl, acyl, alkylamido, hydrazido, silyl, aldehyde, keto, C2-4 alkenyl and/or alkynyl groups and one nitrogen is covalently bound to the tungsten atom.

In some embodiments, at least one DAD is represented by the formula

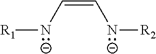

where the DAD ligand consists of a doubly anionic system where both nitrogen atoms are capable of being covalently bound to the tungsten atom. Each of R₁ and R₂ are independently selected from H, C1-6 alkyl, aryl, acyl, alkylamido, hydrazido, silyl, aldehyde, keto, C2-4 alkenyl and/or alkynyl groups and one nitrogen is covalently bound to the tungsten atom.

The neutral donor ligand can be any ligand that is neutral and can leave easily. In some embodiments, x is 1 or more, meaning that the compound includes at least one neutral donor ligand. In one or more embodiments, the neutral donor comprises one or more of CO, acetonitrile, pyridine, ammonia, ethylenediamine, and/or triphenylphosphine.

The anionic or dianionic ligand can be any suitable ligand. In some embodiments, z is 1 or more, meaning that the compound includes at least one anionic or dianionic ligand. In one or more embodiments, at least one R is a cyclopentadienyl ring, an amide, allyl, alkyl, amidinate, amidate, guanidinate, alkoxide, acetylide, vinyl, beta-diketonates, beta-ketiminates and/or beta-diketiminates.

The tungsten-containing process gas may be provided in one or more pulses or continuously. The flow rate of the tungsten-containing gas can be any suitable flow rate including, but not limited to, flow rates is in the range of about 1 to about 5000 sccm, or in the range of about 2 to about 4000 sccm, or in the range of about 3 to about 3000 sccm or in the range of about 5 to about 2000 sccm. The tungsten-containing precursor can be provided at any suitable pressure including, but not limited to, a pressure in the range of about 5 mTorr to about 25 Torr, or in the range of about 100 mTorr to about 20 Torr, or in the range of about 5 Torr to about 20 Torr, or in the range of about 50 mTorr to about 2000 mTorr, or in the range of about 100 mTorr to about 1000 mTorr, or in the range of about 200 mTorr to about 500 mTorr.

The period of time that the substrate is exposed to the tungsten-containing gas may be any suitable amount of time necessary to allow the tungsten precursor to form an adequate nucleation layer atop the substrate surfaces. For example, the process gas may be flowed into the process chamber for a period of about 0.1 seconds to about 90 seconds. In some time-domain ALD processes, the tungsten-containing gas is exposed the substrate surface for a time in the range of about 0.1 sec to about 90 sec, or in the range of about 0.5 sec to about 60 sec, or in the range of about 1 sec to about 30 sec, or in the range of about 2 sec to about 25 sec, or in the range of about 3 sec to about 20 sec, or in the range of about 4 sec to about 15 sec, or in the range of about 5 sec to about 10 sec.

In some embodiments, an inert gas may additionally be provided to the process chamber at the same time as the tungsten-containing gas. The inert gas may be mixed with the tungsten-containing gas (e.g., as a diluent gas) or separately and can be pulsed or of a constant flow. In some embodiments, the inert gas is flowed into the processing chamber at a constant flow in the range of about 1 to about 10000 sccm. The inert gas may be any inert gas, for example, such as argon, helium, neon, combinations thereof, or the like. In one or more embodiments, the tungsten-containing gas is mixed with argon prior to flowing into the process chamber.

The temperature of the substrate during deposition can be controlled, for example, by setting the temperature of the substrate support or susceptor. In some embodiments the substrate is held at a temperature in the range of about 300° C. to about 475° C., or in the range of about 350° C. to about 450° C. In one or more embodiments, the substrate is maintained at a temperature less than about 475° C., or less than about 450° C., or less than about 425° C., or less than about 400° C., or less than about 375° C.

In addition to the foregoing, additional process parameters may be regulated while exposing the substrate to the tungsten-containing process gas. For example, in some embodiments, the process chamber may be maintained at a pressure of about 0.3 to about 90 Torr.

Next, at 108, the process chamber (especially in time-domain ALD) may be purged using an inert gas. (This may not be needed in spatial ALD processes as there is a gas curtain separating the reactive gases.) The inert gas may be any inert gas, for example, such as argon, helium, neon, or the like. In some embodiments, the inert gas may be the same, or alternatively, may be different from the inert gas provided to the process chamber during the exposure of the substrate to the first process gas at 106. In embodiments where the inert gas is the same, the purge may be performed by diverting the first process gas from the process chamber, allowing the inert gas to flow through the process chamber, purging the process chamber of any excess first process gas components or reaction byproducts. In some embodiments, the inert gas may be provided at the same flow rate used in conjunction with the first process gas, described above, or in some embodiments, the flow rate may be increased or decreased. For example, in some embodiments, the inert gas may be provided to the process chamber at a flow rate of about 0 to about 10000 sccm to purge the process chamber. In spatial ALD, purge gas curtains are maintained between the flows of reactive gases and purging the process chamber may not be necessary. In some embodiment, however, the process chamber may be purged with an inert gas.

The flow of inert gas may facilitate removing any excess first process gas components and/or excess reaction byproducts from the process chamber to prevent unwanted gas phase reactions of the first and second process gases. For example, the flow of inert gas may remove excess tungsten-containing gas from the process chamber, preventing a reaction between the tungsten precursor and a subsequent reactive gas.

Next, at 110, the substrate is exposed to a second process gas for a second period of time. The second process gas reacts with the tungsten-containing compound on the substrate surface to create a deposited film. The second process gas can have an important impact on the resulting tungsten film. For example, when the second process gas is H₂, a tungsten film is deposited, but when the second reactive gas is silane or disilane, a tungsten silicide film is deposited.

In some embodiments, the second reactive gas comprises hydrogen and the resulting film formed is a tungsten film. The hydrogen gas may be supplied to the substrate surface at a flow rate greater than the tungsten-containing gas concentration. In one or more embodiments, the flow rate of H₂ is greater than about 1 time that of the tungsten-containing gas, or about 100 times that of the tungsten-containing gas, or in the range of about 3000 to 5000 times that of the tungsten-containing gas. The hydrogen gas can be supplied, in time-domain ALD, for a time in the range of about 1 sec to about 30 sec, or in the range of about 5 sec to about 20 sec, or in the range of about 10 sec to about 15 sec. The hydrogen gas can be supplied at a pressure in the range of about 1 Torr to about 30 Torr, or in the range of about 5 Torr to about 25 Torr, or in the range of about 10 Torr to about 20 Torr, or up to about 50 Torr. The substrate temperature can be maintained at any suitable temperature. In one or more embodiments, the substrate is maintained at a temperature less than about 475° C., or at a temperature about the same as that of the substrate during the tungsten-containing film deposition.

In some embodiments, the second reactive gas comprises hydrogen radicals. The hydrogen radicals can be generated by any suitable means including exposure of hydrogen gas to a “hot-wire”. As used in this specification and the appended claims, the term “hot-wire” means any element that can be heated to a temperature sufficient to generate radicals in a gas flowing about the element. This is also referred to as a heating element.

The second reactive gas (e.g., hydrogen), while passing the hot wire, or heating element, becomes radicalized. For example, H₂ passing a hot tungsten wire can result in the generation of H*. These hydrogen radicals are more reactive than ground state hydrogen atoms.

Next, at 112, process chamber may be purged using an inert gas. The inert gas may be any inert gas, for example, such as argon, helium, neon, or the like. In some embodiments, the inert gas may be the same, or alternatively, may be different from the inert gas provided to the process chamber during previous process steps. In embodiments where the inert gas is the same, the purge may be performed by diverting the second process gas from the process chamber, allowing the inert gas to flow through the process chamber, purging the process chamber of any excess second process gas components or reaction byproducts. In some embodiments, the inert gas may be provided at the same flow rate used in conjunction with the second process gas, described above, or in some embodiments, the flow rate may be increased or decreased. For example, in some embodiments, the inert gas may be provided to the process chamber at a flow rate of about 0 to about 10,000 sccm to purge the process chamber.

While the generic embodiment of the processing method shown in the FIGURE includes only two pulses of reactive gases, it will be understood that this is merely exemplary and that additional pulses of reactive gases may be used. For example, a nitride film of some embodiments can be grown by a first pulse containing a precursor gas like tungsten pentachloride, a second pulse with a reducing agent followed by purging and a third pulse for nitridation. The pulses can be repeated in their entirety or in part. For example all three pulses could be repeated or only two can be repeated. This can be varied for each cycle.

Next, at 114, it is determined whether the tungsten-containing layer has achieved a predetermined thickness. If the predetermined thickness has not been achieved, the method 100 returns to 104 to continue forming the tungsten-containing layer until the predetermined, or desired, thickness is reached. Once the predetermined thickness has been reached, the method 100 can either end or proceed to 116 where a bulk deposition process may be performed to deposit the remaining thickness of the tungsten-containing layer. In some embodiments, the bulk deposition process may be a CVD process. Upon completion of deposition of the tungsten-containing layer to a desired thickness, the method 100 generally ends and the substrate can proceed for any further processing. For example, in some embodiments, a CVD process may be performed to bulk deposit the tungsten-containing layer to a target thickness. For example in some embodiments, the tungsten-containing layer may be deposited via ALD or CVD reaction of the tungsten precursor and hydrogen radicals to form a total layer thickness of about 10 to about 10,000 Å, or in some embodiments, about 10 to about 1000 Å, or in some embodiments, about 500 to about 5,000 Å.

One or more embodiments of the disclosure are directed to processing methods comprising exposing a substrate to a first reactive gas comprising a tungsten-containing compound comprising a compound with the representative formula W(ND)ₓ(DAD)_{y}R_{z}, where each ND is a neutral donor, each DAD is a diazadiene, each R is an anionic or dianionic ligand and x is in the range of 0 to 4, y is in the range of 1 to 3 and z is in the range of 0 to 4 and a second reactive gas to form a tungsten-containing film. In some embodiments, the substrate is exposed to the first reactive gas and the second reactive gas sequentially. In one or more embodiments, the substrate is exposed to the first reactive gas and the second reactive gas simultaneously.

In some embodiments, the second reactive gas comprises a hydrogen-containing compound and the tungsten-containing film is a tungsten film.

In one or more embodiments, the second reactive gas comprises a silicon-containing compound and the tungsten-containing film comprises tungsten silicide (WSiₓ).

In some embodiments, the tungsten-containing film comprises greater than or equal to about 95 atomic percent tungsten. In one or more embodiments, The sum of C, N, O and halogen atoms is less than or equal to about 5 atomic percent of the tungsten-containing film.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A metal coordination complex having a formula represented by W(ND)ₓ(DAD)_{y}R_{z}, where each ND is a neutral donor, each DAD is a diazadiene, each R is an anionic or dianionic ligand and x is in the range of 0 to 4, y is in the range of 1 to 3, z is in the range of 0 to 4 and x+z is greater than or equal to 1.

2. The metal coordination complex of claim 1, wherein at least one DAD is represented by the formula 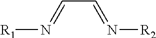
where each of R₁ and R₂ are independently selected from H, C1-6 alkyl, aryl, acyl, alkylamido, hydrazido, silyl, aldehyde, keto, C2-4 alkenyl and/or alkynyl groups.

3. The metal coordination complex of claim 1, wherein at least one DAD is represented by the formula 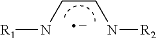
where the DAD consists of a delocalized radical anion and is negatively charged and each of R₁ and R₂ are independently selected from H, C1-6 alkyl, aryl, acyl, alkylamido, hydrazido, silyl, aldehyde, keto, C2-4 alkenyl and/or alkynyl groups and one nitrogen is covalently bound to the tungsten atom.

4. The metal coordination complex of claim 1, wherein at least one DAD is represented by the formula 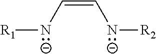
where the DAD ligand consists of a doubly anionic system where both nitrogen atoms are capable of being covalently bound to the tungsten atom and each of R₁ and R₂ are independently selected from H, C1-6 alkyl, aryl, acyl, alkylamido, hydrazido, silyl, aldehyde, keto, C2-4 alkenyl and/or alkynyl groups.

5. The metal coordination complex of claim 1, wherein x is 1 or more and the neutral donor is CO.

6. The metal coordination complex of claim 1, wherein z is 1 or more and at least one R is a cyclopentadienyl ring.

7. A processing method comprising sequentially exposing a substrate to a first reactive gas comprising a tungsten-containing compound comprising a compound with the representative formula W(ND)ₓ(DAD)_{y}R_{z}, where each ND is a neutral donor, each DAD is a diazadiene, each R is an anionic or dianionic ligand and x is in the range of 0 to 4, y is in the range of 1 to 3, z is in the range of 0 to 4 and x+z is greater than or equal to 1 and a second reactive gas to form a tungsten-containing film.

8. The method of claim 7, wherein the second reactive gas comprises a hydrogen-containing compound and the tungsten-containing film is a tungsten film.

9. The method of claim 7, wherein the second reactive gas comprises a silicon-containing compound and the tungsten-containing film comprises tungsten silicide (WSiₓ).

10. The method of claim 9, wherein at least one DAD is represented by the formula 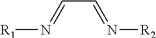
where each of R1 and R2 are independently selected from H, C1-6 alkyl, aryl, acyl, alkylamido, hydrazido, silyl, aldehyde, keto, C2-4 alkenyl and/or alkynyl groups.

11. The method of claim 9, wherein at least one DAD is represented by the formula 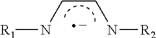
where the DAD consists of a delocalized radical anion and is negatively charged and each of R₁ and R₂ are independently selected from H, C1-6 alkyl, aryl, acyl, alkylamido, hydrazido, silyl, aldehyde, keto, C2-4 alkenyl and/or alkynyl groups and one nitrogen is covalently bound to the tungsten atom.

12. The method of claim 9, wherein at least one DAD is represented by the formula 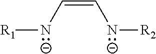
where the DAD ligand consists of a doubly anionic system where both nitrogen atoms are capable of being covalently bound to the tungsten atom and each of R₁ and R₂ are independently selected from H, C1-6 alkyl, aryl, acyl, alkylamido, hydrazido, silyl, aldehyde, keto, C2-4 alkenyl and/or alkynyl groups.

13. The method of claim 9, wherein x is 1 or more and the neutral donor is CO.

14. The method of claim 9, wherein z is 1 or more and at least one R is a cyclopentadienyl ring.

15. The method of claim 9, wherein the tungsten-containing film comprises greater than or equal to about 95 atomic percent tungsten.

16. The method of claim 9, wherein the sum of C, N, O and halogen atoms is less than or equal to about 5 atomic percent of the tungsten-containing film.

17. A processing method comprising exposing a substrate to a first reactive gas comprising a tungsten-containing compound comprising a compound with the representative formula W(ND)ₓ(DAD)_{y}R_{z}, where each ND is a neutral donor, each DAD is a diazadiene, each R is an anionic or dianionic ligand and x is in the range of 0 to 4, y is in the range of 1 to 3, z is in the range of 0 to 4 and x+z is greater than or equal to 1, and a second reactive gas to form a tungsten-containing film.

18. The method of claim 17, wherein the substrate is exposed to the first reactive gas and the second reactive gas sequentially.

19. The method of claim 17, wherein the substrate is exposed to the first reactive gas and the second reactive gas simultaneously.

20. The method of claim 17, wherein x is 1 or more and comprises CO, z is one or more and comprises a cyclopentadienyl group.
